(19) United States
(12) Patent Application Publication
(10) Pub. No.: US 2010/0321870 A1
(43) Pub. Date: Dec. 23, 2010

(54) ELECTRONIC DEVICE

(75) Inventors: Yuichi HIRAI, Ome-shi (JP); Yuji NAKAJIMA, Nishitama-gun (JP); Toshikazu SHIROISHI, Hamura-shi (JP); Takayuki ARISAKA, Fussa-shi (JP); Yasuyuki SUZUKI, Tachikawa-shi (JP)

Correspondence Address: KNOBBE MARTENS OLSON & BEAR LLP, 2040 MAIN STREET, FOURTEENTH FLOOR, IRVINE, CA, 92614, US

(73) Assignee: Kabushiki Kaisha Toshiba, Tokyo (JP)

(21) Appl. No.: 12/819,142

(22) Filed: Jun. 18, 2010

(30) Foreign Application Priority Data
Jun. 23, 2009 (JP) 2009-149110

(51) Int. Cl. H05K 7/00

(52) U.S. Cl. 361/679.01

(57) ABSTRACT

According to one embodiment, an electronic device includes an outer cover, ribs, and reinforcement beads. The outer cover constitutes an enclosure of a display section, and covers the back of a display unit to be assembled in the display section. The ribs are formed integral with an inner wall of the outer cover into a honeycomb structure arrangement constituted of a plurality of cells. The reinforcement beads are formed integral with the inner wall of the outer cover from the vicinity of each of both hinge side corners where the hinge is fastened on, to the vicinity of each of both rotation end corners located at positions on the outer cover diagonal with respect to the hinge side corners.

### CROSS-REFERENCE TO RELATED APPLICATIONS

This application is based upon and claims the benefit of priority from Japanese Patent Application No. 2009-149110, filed Jun. 23, 2009, the entire contents of which are incorporated herein by reference.

### FIELD

Embodiments described herein relate generally to an electronic device in which rigidity of the enclosure of the display section is enhanced.

### BACKGROUND

Since a notebook computer is often carried, reducing the thickness and weight thereof are requested. When carried, the notebook computer may be inserted in a bag with small articles such as writing tools, documents, and the like in some cases. A display module assembled in the display section is fragile. Hence sufficient rigidity and toughness are required of the enclosure constituting the display section.

A notebook computer that comprises an upper housing partially provided with a honeycomb structure at the back of the display module in the display section is disclosed in Jpn. Pat. Appln. KOKAI Publication No. 2008-234100. The display section of this notebook computer is constituted of a cosmetic cover, upper housing, antenna, display module, and bezel.

The upper housing is formed into a box-like shape a periphery of which is bent. A part of the periphery and the other part of the periphery are connected to each other by four main bridges. The main bridges are joined together into one body at a center of the upper housing. Sub-bridges consisted of a honeycomb structure are formed in areas surrounded by the periphery and main bridges. The sub-bridge is constituted of ribs with a honeycomb structure forming opening cells, which look like a regular hexagon shaped frames. The opening cell is formed in such a manner that an open ratio in the area ratio of about 40 to 60% is obtained.

Incidentally, in order to realize reduction in thickness and weight of the notebook computer, it is desired to make the enclosure of the display side metallic. However, it is disclosed in Jpn. Pat. Appln. KOKAI Publication No. 2008-234100 that an opening part must be provided when the housing is made metallic, because the sensitivity of the antenna built in the housing of the display side is lowered. In this document, it is pointed out that the strength of protecting the display module is lowered by providing the opening. Further, the decorative function of the display side enclosure as the outer cover must be fulfilled. Hence, it is determined in the document that it is difficult to further reduce the thickness and weight by constituting the enclosure of the display side as a single body. As a result of this, the function as the structure and function as the outer cover are separated from each other in Jpn. Pat. Appln. KOKAI Publication No. 2008-234100 in the enclosure of the display side. The former is defined as an upper housing, and latter is defined as a cosmetic cover.

However, when the enclosure configured to protect the display unit is constituted by functionally separating the enclosure into the two components of the upper housing and cosmetic cover, the manufacturing processes and quality control processes are increased correspondingly, and hence the cost is also increased.

Further, when the notebook computer is used, the display section is rotated with respect to the main body around the hinges as the center. At this time, the display section may be operated to rotate by being gripped by one hand at a right or left sided position. When the display unit to be provided in the display section becomes large, the frictional resistance of the hinges to hold the display section at an arbitrary angle also becomes large. Therefore, it is necessary for the display section to be provided with sufficient rigidity to withstand the torsion to be applied thereto when the display section is rotated in addition to the pressing load to be applied thereto in the thickness direction from outside.

The notebook computer described in Jpn. Pat. Appln. KOKAI Publication No. 2008-234100 has a sub-bridge consisted of the honeycomb structure in the upper housing. However, in the upper housing, although the sub-bridge includes the honeycomb structure, the opening cells are provided inside the honeycomb. Therefore the original torsional rigidity of the honeycomb structure cannot be sufficiently exerted.

### BRIEF DESCRIPTION OF THE DRAWINGS

FIG. 1 is a perspective view showing an electronic device of a first embodiment by partially cutting off a display section.

FIG. 2 is a front view of an enclosure of the display section shown in FIG. 1.

FIG. 3 is a cross-sectional view showing the enclosure of the display section along line F3-F3 in FIG. 2.

FIG. 4 is an enlarged cross-sectional view of a part F4 in FIG. 3.

FIG. 5 is a cross-sectional view schematically showing the cross-sectional view of the enclosure shown in FIG. 3.

FIG. 6 is a cross-sectional view schematically showing a modification example of the enclosure shown in FIG. 3.

FIG. 7 is a cross-sectional view schematically showing a modification example of the enclosure shown in FIG. 3.

FIG. 8 is a cross-sectional view schematically showing a modification example of the enclosure shown in FIG. 3.

FIG. 9 is an enlarged perspective view of a part F9 in FIG. 2.

FIG. 10 is an enlarged perspective view of a part F10 in FIG. 2.

FIG. 11 is an enlarged perspective view of a part F11 in FIG. 2.

FIG. 12 is an enlarged perspective view of a part F12 in FIG. 2.

FIG. 13 is a front view showing an enclosure of a display section of an electronic device of a second embodiment.

FIG. 14 is an enlarged perspective view of a part F14 in FIG. 13.

FIG. 15 is an enlarged perspective view of a part F15 in FIG. 13.

FIG. 16 is an enlarged perspective view of a part F16 in FIG. 13.

FIG. 17 is an enlarged perspective view of a part F17 in FIG. 13.

FIG. 18 is an enlarged perspective view of a part F18 in FIG. 13.

### DETAILED DESCRIPTION

According to an embodiment, an electronic device comprises an outer cover, ribs, and reinforcement beads. The outer cover constitutes an enclosure of a display section, and covers the back of a display unit to be assembled in the display section. The display section is coupled to a main body by hinges, and is held at an angle of rotation by the rotation resistance of the hinges. The ribs are formed integral with an inner wall of the outer cover into a honeycomb structure arrangement constituted of a plurality of cells. The reinforcement beads are formed integral with the inner wall of the outer cover from the vicinity of each of both hinge side corners where the hinges are fastened on, to the vicinity of each of both rotation end corners located at positions on the outer cover diagonal with respect to the hinge side corners.

As described above, embodiments of the electronic device includes the enclosure with high rigidity against a pressing load and torsional stress without increasing the number of parts and weight of the enclosure of the display section.

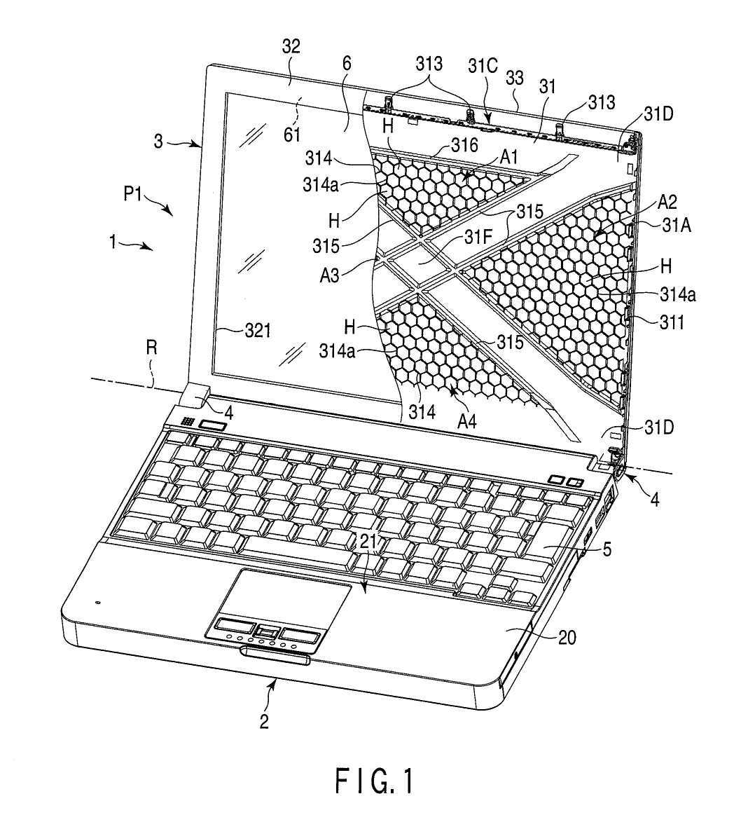

Various embodiments will be described hereinafter with reference to the accompanying drawings. An electronic device 1 of a first embodiment will be described below with reference to FIGS. 1 to 9. The electronic device 1 shown in FIG. 1 is a notebook portable computer, in which a display section 3 is coupled to a main body 2 by hinges 4. It should be noted that in this description, the near side viewed from the user side is called the “front”, far side is called “rear”. It is also defined “upper”, “lower”, “left”, and “right” according to the user side respectively. Further, a state where the display section 3 is laid on top of the main body 2 is called the “closed posture” of the electronic device 1, and a state where the display section 3 is vertically raised with respect to the main body 2 is call the “opened posture P1” of the electronic device 1. Further, an operation of putting the electronic device 1 into the closed posture is expressed as “closing”, and an operation of putting the device 1 into the “opened posture P1” is expressed as “opening” in some cases.

The main body 2 is provided with a keyboard 5 serving as an input means on a top surface 21 of a first enclosure 20 constituting an outer shell as shown in FIG. 1. A liquid crystal display which is an example of the display unit 6 is assembled in the display section 3. As the display unit 6, an organic electroluminescence display, plasma display, surface-conduction electron-emitter display, and the like can be employed in addition to the liquid crystal display. Further, as an input means for enabling an input operation from the surface of the display unit 6, for example, a digitizer or touch panel may be assembled in the display section 3. The hinges 4 couple the main body 2 and display section 3 to each other, and have rotation resistance enough to hold the weight of the display section 3. Therefore the display section 3 is held at the angle when the display section 3 is turned at a certain angle with respect to the main body 2.

The display section 3 is provided with an outer cover 31 and mask 32 constituting a second enclosure. The outer cover 31 covers the back surface 6a of the display unit 6 built in the display section 3. The mask 32 includes an opening 321 corresponding to a display area of the display unit 6, and covers the outer peripheral edge 61 of the display unit 6 from the front. The outer cover 31 includes supports 311 in order to retain the display unit 6 inside the right and left sidewalls 31A.

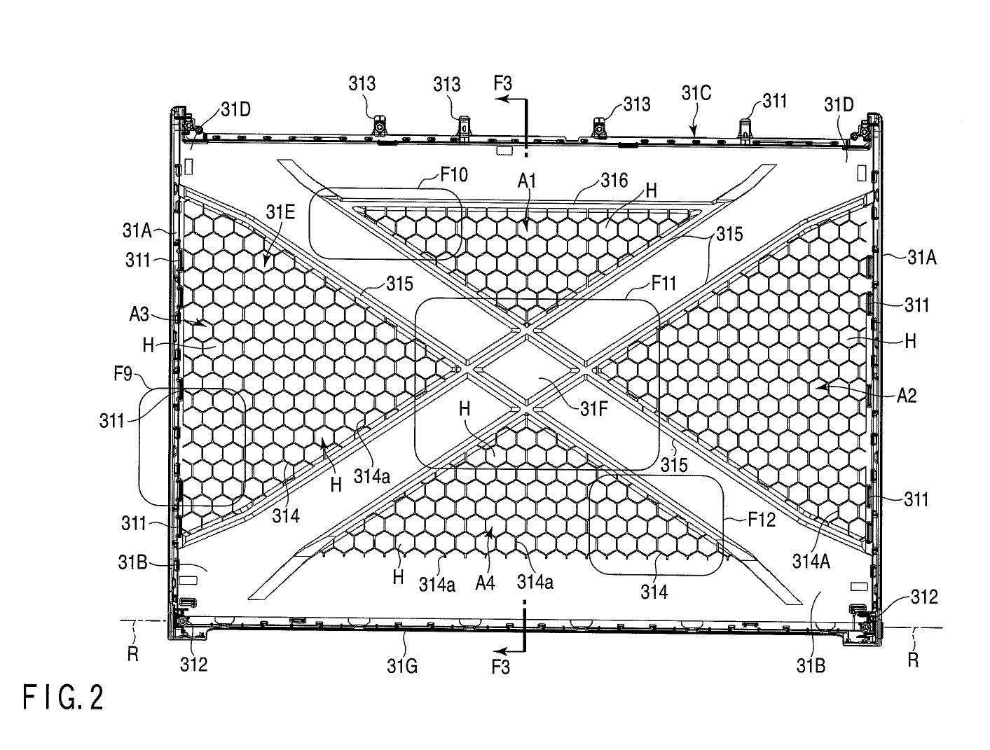

As shown in FIG. 2, the supports 311 are dispersedly arranged at several positions. Further, the outer cover 31 includes proximal parts 312 used to directly attach the hinges 4 at hinge side corners 31B which become the lower end in the opened posture P1. Further, a rotation end 31C of the outer cover 31 which becomes an upper end in the opened posture 1 is opened at a part between rotation end corners 31D. An antenna for wireless communication is arranged in the vicinity of this part. Further, the outer cover 31 includes stems 313 to fasten an auxiliary cover 33 used to cover the opened part along the outer surface of the outer cover 31 at several positions. It should be noted that an antenna for infrared communication may also be arranged together with the antenna for wireless communication.

As shown in FIG. 2, the outer cover 31 is provided with ribs 314 and 314a, and reinforcement beads 315 on the inner wall 31E. The ribs 314 and 314a are each arranged in a honeycomb structure constituted of a plurality of regular-hexagonal cells H. Each cell H includes a longitudinal rib 314a extending in a direction perpendicular to the rotational axis R of the hinge 4. It should be noted that hereinafter, in this description, the term “rib 314” includes a diagonally arranged rib 314, and longitudinal rib 314a unless the “longitudinal rib 314a” is referred to. Further, the reinforcement bead 315, which has a cross-sectional shape of a trapezoid, is larger in width than the rib 314, and reinforcement beads 315 are provided in twos in parallel with each other. The reinforcement beads 315 diagonally extend from the vicinity of each of both the hinge side corners 31B to the vicinity of each of both the rotation end corners 31D located at positions on the outer cover 31 diagonal with respect to the hinges 4, and intersect each other at the central area 31F.

In this embodiment, a reinforcement bead 316 is further provided. The reinforcement bead 316 is arranged on the rotation end 31C in parallel with the rotational axis R. Each ends of the reinforcement bead 316 is connected to each of the reinforcement beads 315 arranged in the directions along the diagonal lines. The ribs 314 of the honeycomb structure are arranged to fill the outside areas of the reinforcement beads 315 provided in twos in parallel with each other. The ribs 314 of the honeycomb structure are arranged in the four areas in a pattern in which the ribs 314 have continuity between each other. An upper area A1 is surrounded by the reinforcement bead 316 on the rotation end 31C, and reinforcement beads 315 extending along the diagonal lines. A right area A2 and left area A3 are surrounded by right and left sidewalls 31A of the outer cover 31, and reinforcement beads 315 extending along the diagonal lines. A lower area A4 is surrounded by an edge 31G of the outer cover 31 closer to the main body 2, and the reinforcement beads 315 extending along the diagonal lines.

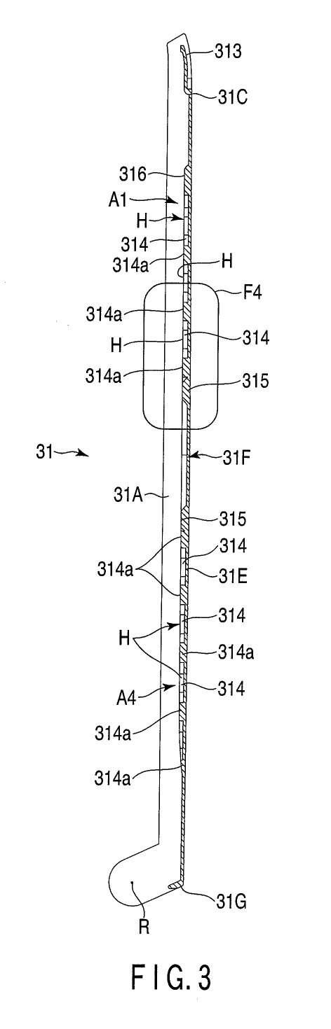

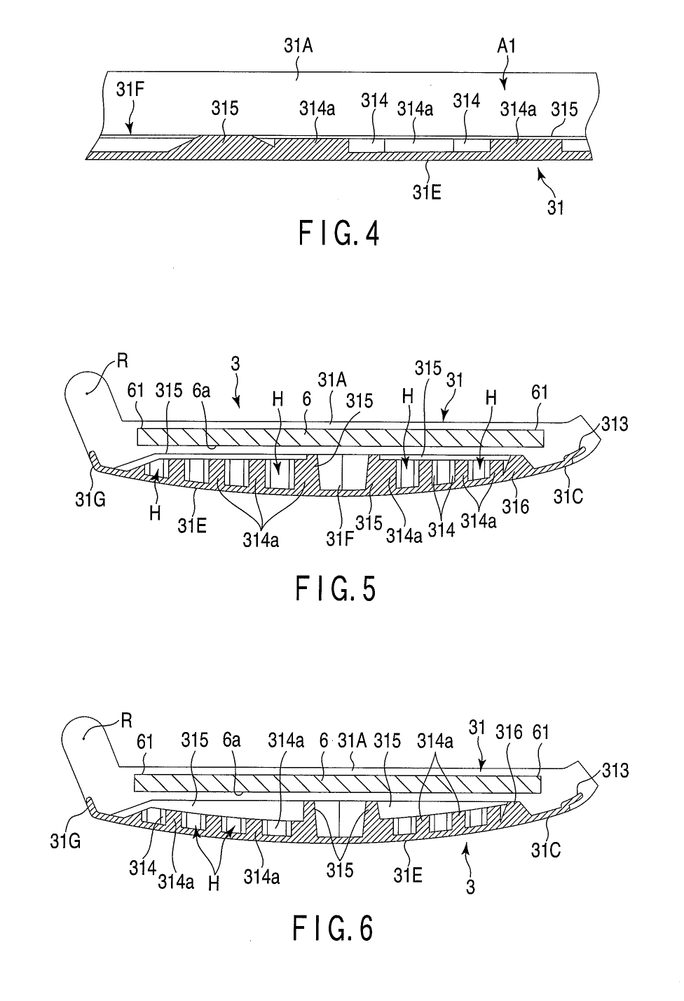

Each of the ribs 314 and reinforcement beads 315 and 316 is formed integral with the outer cover 31 as shown in FIGS. 3 and 4, and has a height larger than a thickness of the inner wall 31E. The rib 314 is formed slightly lower than the reinforcement beads 315 and 316 as shown in FIG. 4, although the state is apparently almost invisible in FIG. 3. In this embodiment, the rib 314 is lower than the reinforcement beads 315 and 316 by about 0.1 mm. Further, although almost invisible in FIG. 3, the outer cover 31 swells out at the central area 31F thereof as schematically shown in FIG. 5, and forms a gentle curved surface as a whole. At this time, the rib 314 and reinforcement beads 315 and 316 are formed in such a manner the heights of the rib 314 and beads 315 and 316 are parallel with the display unit 6. That is, the rib 314 and reinforcement bead 315 closer to the central area 31F are higher than the rib 314 and reinforcement beads 315 and 316 on the main body 2 side and rotation end 31C side.

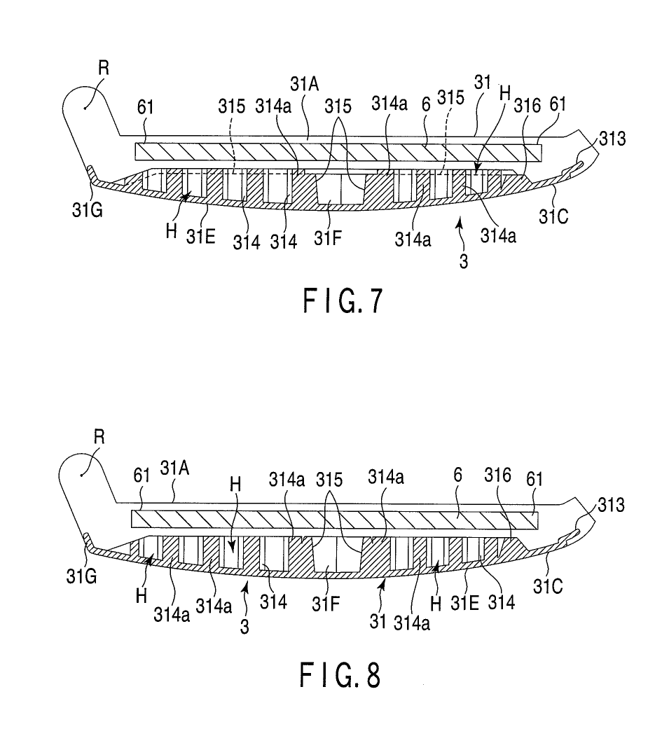

The main purpose of the reinforcement beads 315 formed in the diagonal directions is to receive a surface load applied to the outer cover 31 from outside when the electronic device 1 is in the closed posture. The main purpose of the rib 314 of the honeycomb structure is to enhance the torsional rigidity of the outer cover 31. Therefore, as shown in FIG. 6, the reinforcement bead 315 may be formed to have a height parallel with the display unit 6, and rib 314 may be formed to have a height parallel with the inner wall 31E of the outer cover 31. Further, in order that the surface load applied to the outer cover 31 from outside may not be applied to the display unit 6 as a point load into which the stress is concentrated, the heights of the rib 314 and reinforcement bead 315 are set parallel with the back surface 6a of the display unit 6. The height of the rib 314 may be set higher than the reinforcement beads 315 and 316, as shown in FIG. 7. Further, the heights of the rib 314 and reinforcement beads 315 and 316 may be set at the same height as shown in FIG. 8 so that any part may come in contact with the display unit 6 when the outer cover 31 is curved as a whole.

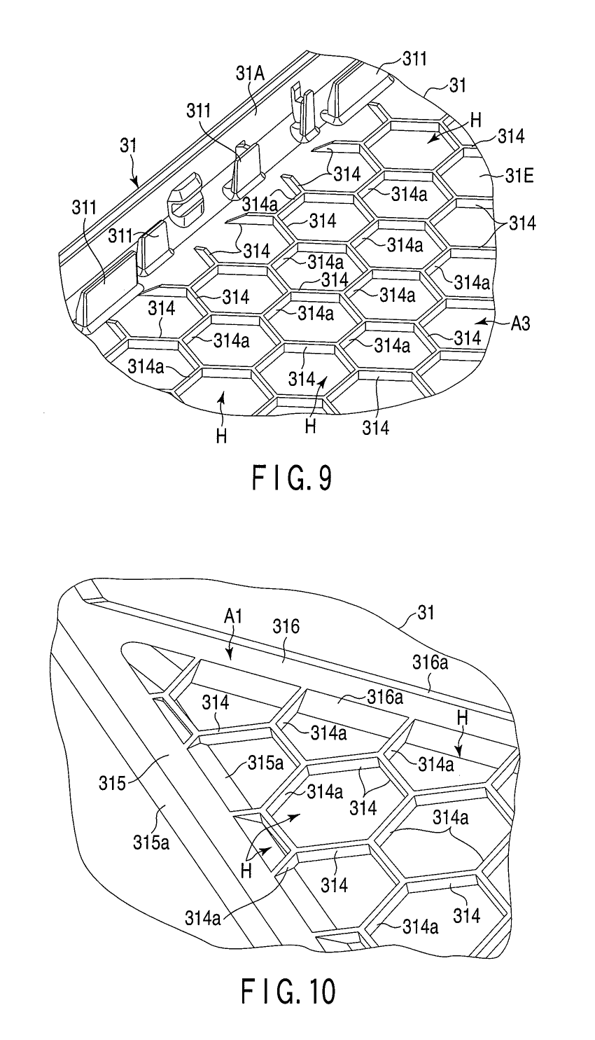

Furthermore, details of the outer cover 31 of this embodiment will be described below. This outer cover 31 retains the display unit 6. The supports 311 for retaining the display unit 6 are formed integral with the outer cover 31. As shown in FIG. 9, the supports 311 are arranged at several positions slightly inside the sidewalls 31A extending from the right and left hinge side corners 31B at right angles to the rotational axis R of the hinge 4. The supports 311 are arranged to face the outer peripheral edge 61 provided with the fastening portion and support portion of the display unit 6. A lead wire connected to the antenna provided on the rotation end 31C of the display section 3 is arranged between the sidewall 31A and supports 311.

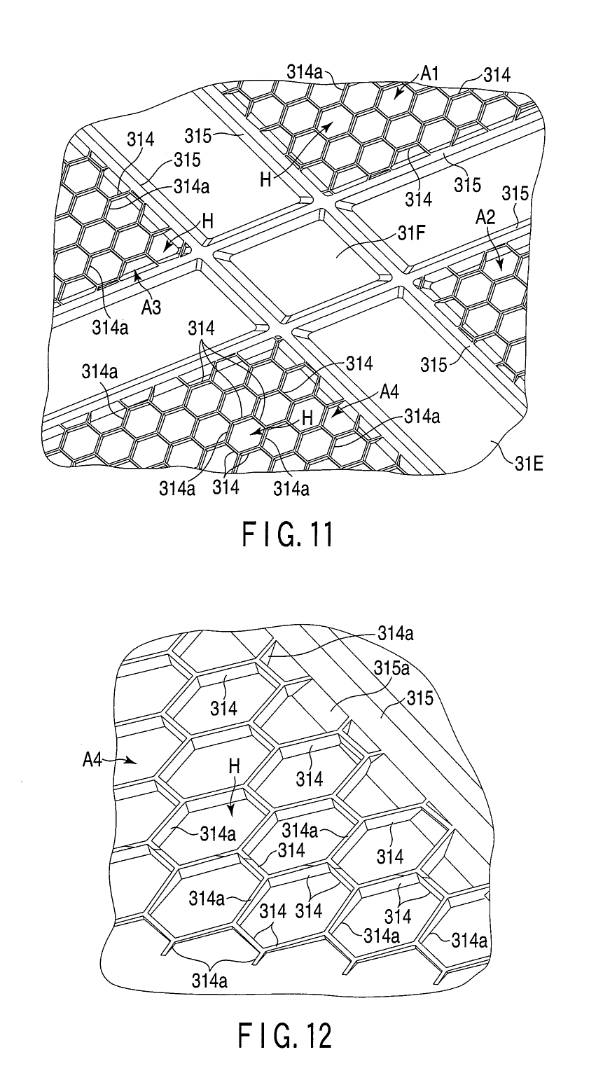

In each of the ribs 314 arranged in the vicinity of the sidewall 31A of the outer cover 31, the height of the rib 314 is gradually decreased just front of the support 311 to the surface of the inner wall 31E of the outer cover 31 as shown in FIG. 9. Further, each of the ribs 314 adjacent to the reinforcement bead 315 or 316 is formed even on the slope 315a or 316a of the reinforcement bead 315 or 316 a cross-sectional shape of which is a trapezoid while the pattern of the honeycomb structure is maintained as shown in FIGS. 10, 11, and 12. The reinforcement beads 315 is provided continuously extending from each hinge side corner 31B to each rotation end corner 31D including the part at which the reinforcement beads 315 intersect each other as shown in FIG. 11. In other words, the reinforcement beads 315 are connected to each other at the central area 31F in such a manner that the beads 315 across each other at the central area 31F. In each of the longitudinal ribs 314a arranged in the lower area A4 at a position close to the main body 2, a lower end thereof extends at right angles to the main body 2. Further, each of the ribs 314 constituting a cell H at a position close to the main body 2 is formed in such a manner that the height of the rib 314 is gradually decreased to the surface of the inner wall 31E of the outer cover 31 from a part thereof farther from the main body 2 to a part thereof closer to the main body 2.

In the electronic device 1 described above, the ribs 314 arranged to form the honeycomb structure, and reinforcement beads 315 extending from the hinge side corners 31B to the rotation end corners 31D located at positions diagonal with respect to the hinge side corners 31B are formed integral with the inner wall 31E of the outer cover 31. Further, of the loads applied to the outer cover 31, the surface load applied from outside is mainly received by the reinforcement beads 315 and 316, and torsional force applied when the display section 3 is rotated by opening or closing is mainly received by the ribs 314 arranged to form the honeycomb structure. The ribs 314 arranged to form the honeycomb structure are formed integral with the outer cover 31, and the inside of each cell H is closed by the inner wall 31E of the outer cover 31.

Therefore, it is possible to reduce the thickness of the outer cover 31 constituting the enclosure of the display section 3 of the electronic device 1 without increasing the number of components in the thickness direction of the display section 3, and improve the rigidity against the surface load and torsional force to be applied to the display section 3. Further, the ribs 314 which are in the outermost peripheral area, and are not connected to the reinforcement beads 315 and 316 are gradually joined to the surface of the inner wall 31E. Hence, the stress transmitted to the ribs 314 is not concentrated at the outermost periphery of the honeycomb structure.

The outer cover 31 is manufactured by die-casting an alloy mainly containing a light metal such as aluminum, magnesium, titanium or the like. The material to be formed is fed from the rotation end 31C of the outer cover 31. The flow of the material in the casting process is set in the direction along the longitudinal rib 314a. In each of the upper area A1, right area A2, left area A3, and lower area A4, the ribs 314 adjacent to the reinforcement beads 315 and 316 are connected to the slopes 315a and 316a. Each of all the ribs 314 which are not connected to the reinforcement beads 315 is formed in such a manner that the height thereof is gradually decreased with respect to the surface of the inner wall 31E of the outer cover 31. Therefore, the material easily flows along the reinforcement beads 315 and ribs 314 at the die-casting operation.

The outer cover 31 is formed into a curved surface slightly swelling out at the central area 31F thereof. The heights of the reinforcement beads 315 are provided in parallel with the display unit 6. Consequently, the strength of the reinforcement beads 315 in the thickness direction at the central area 31F is higher than the strength in the thickness direction at the peripheral part. When a pressing load is applied to the central area 31F of the outer cover 31 while the electronic device is in the closed posture, the central area 31F is not easily bent.

Although the outer cover 31 is made of a conductive alloy, the rotation end 31C thereof is opened. Hence, providing an antenna for wireless communication on the rotation end 31C is not restricted by using the conductive metallic material for the outer cover 31.

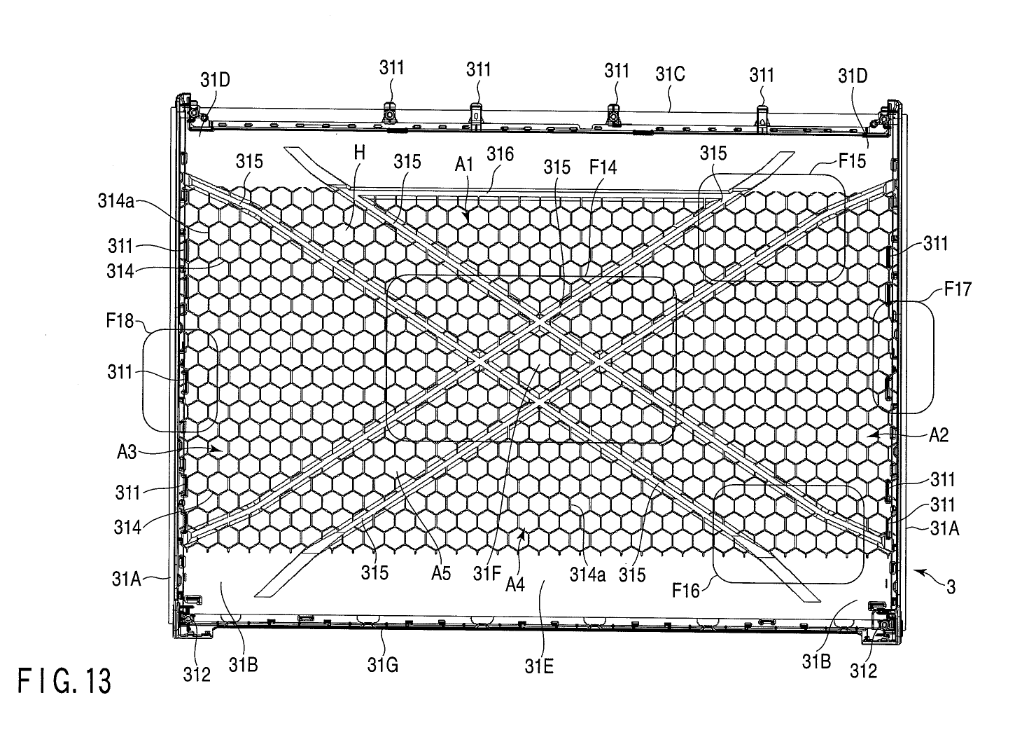

An electronic device 1 of a second embodiment will be described below with reference to FIGS. 13 to 18. The configuration with the same function as that of the electronic device 1 of the first embodiment is denoted by the same reference symbol as the first embodiment in the drawings, and a description thereof is omitted. The electronic device 1 of the second embodiment differs from the electronic device 1 of the first embodiment in the range in which ribs 314 to be arranged on an inner wall 31E of an outer cover 31 to form the honeycomb structure are provided. Since the other configurations of the electronic device 1 of the second embodiment are same as the electronic device of the first embodiment, FIG. 1 and the description thereof in the first embodiment will be referred to the description of the overall electronic device 1.

As shown in FIG. 13, an outer cover 31 of the electronic device 1 includes ribs 314 arranged to form the honeycomb structure in an upper area A1, right area A2, left area A3, and lower area A4. The outer cover 31 further comprises ribs 314 arranged to form the honeycomb structure in an on-diagonal line area A5 between reinforcement beads 315 arranged in parallel with each other. The ribs 314 arranged in the on-diagonal line area A5 are arranged in a pattern continuously with the pattern of the ribs 314 arranged in the upper area A1, right area A2, left area A3, and lower area A4. Therefore, the ribs 314 arranged on the entire area of the inner wall 31E to form the uniform honeycomb structure, and reinforcement beads 315 arranged in the diagonal directions are combined with each other to form a composite structure.

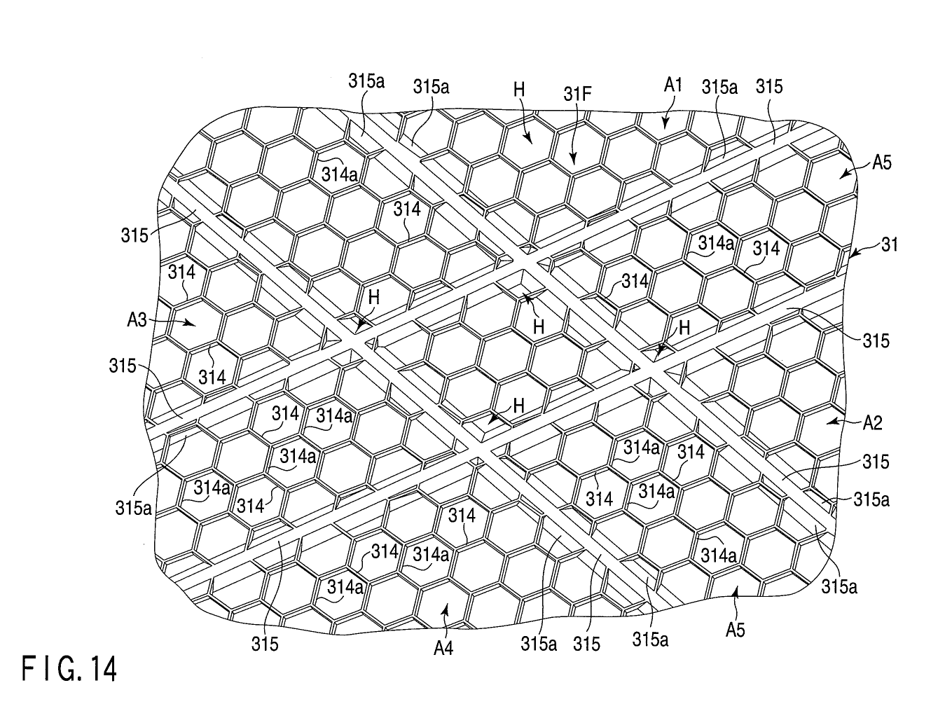

In this embodiment, the ribs 314 formed on the on-diagonal line area A5 of the part at which the reinforcement beads 315 intersect each other, and ribs 314 formed on the upper area A1, right area A2, left area A3, and lower area A4 side are arranged in such a manner that each of four intersection portions of the reinforcement beads 315 is surrounded by one cell H, as shown in FIG. 14. In other words, the size of the cell H of the honeycomb structure, and the interval between the reinforcement beads 315 are set in such a manner that each of the intersection portions of the reinforcement beads 315 is fitted into one cell H.

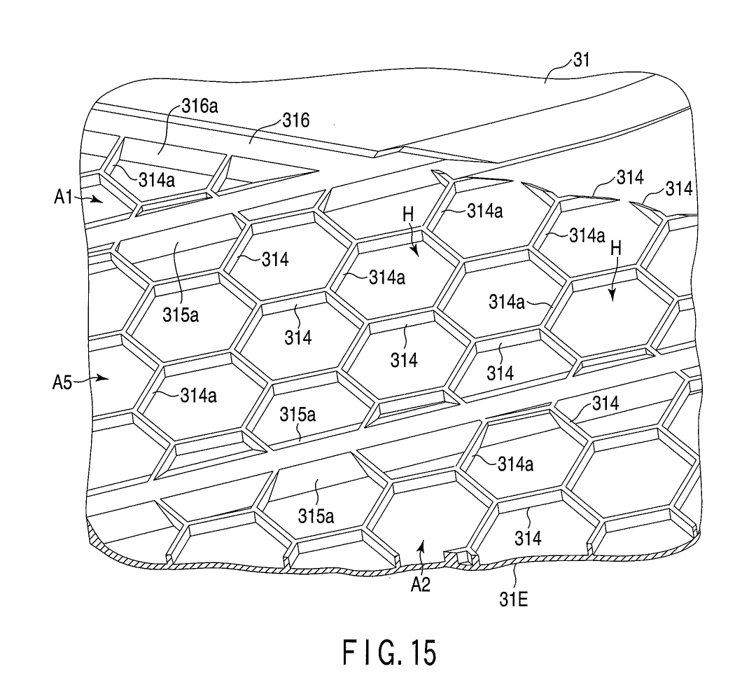

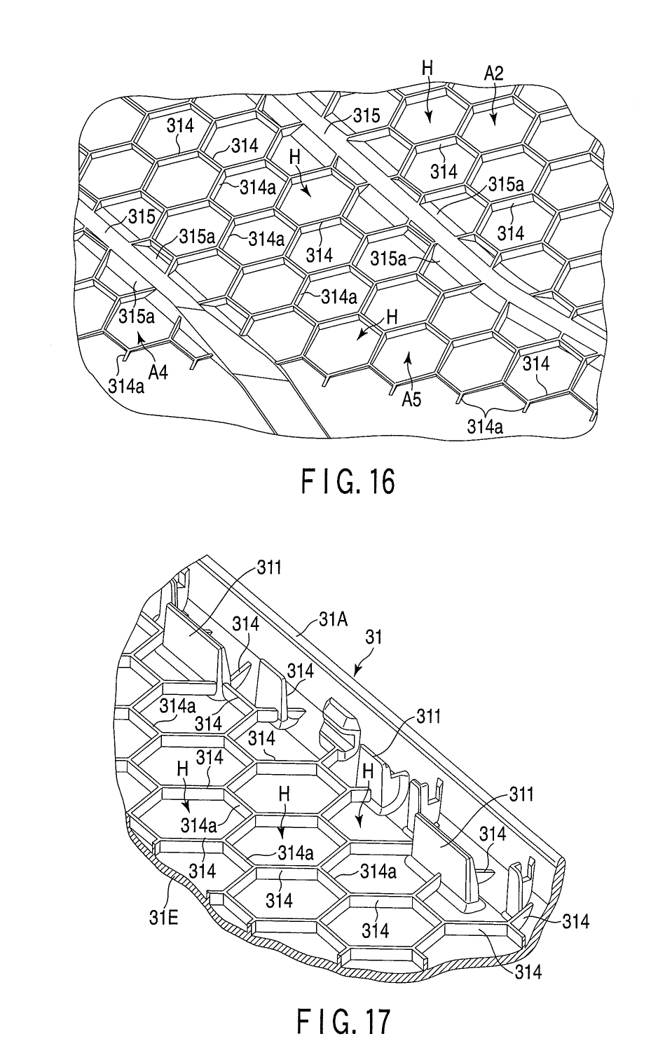

The ribs 314 in the on-diagonal line area A5, and closer to the rotation end corner 31D are provided up to a position on an extension line from the reinforcement bead 316 provided along the rotation end 31C as shown in FIG. 15. Further, the ribs 314 to be arranged at the upper end in the opened posture P1 are formed in such a manner that the heights of the ribs 314 are gradually decreased to the surface of the inner wall 31E along the same plane as the slope of the reinforcement bead 316 on the upper end. Likewise, as shown in FIG. 16, the ribs 314 in the on-diagonal line area A5, and closer to the hinge side corner 31B are provided up to the same position as the ribs 314 in the lower area A4 closer to the main body 2. The heights of the ribs 314 are also gradually decreased to the surface of the inner wall 31E at the same rate of decrease as the ribs 314 in the lower area A4.

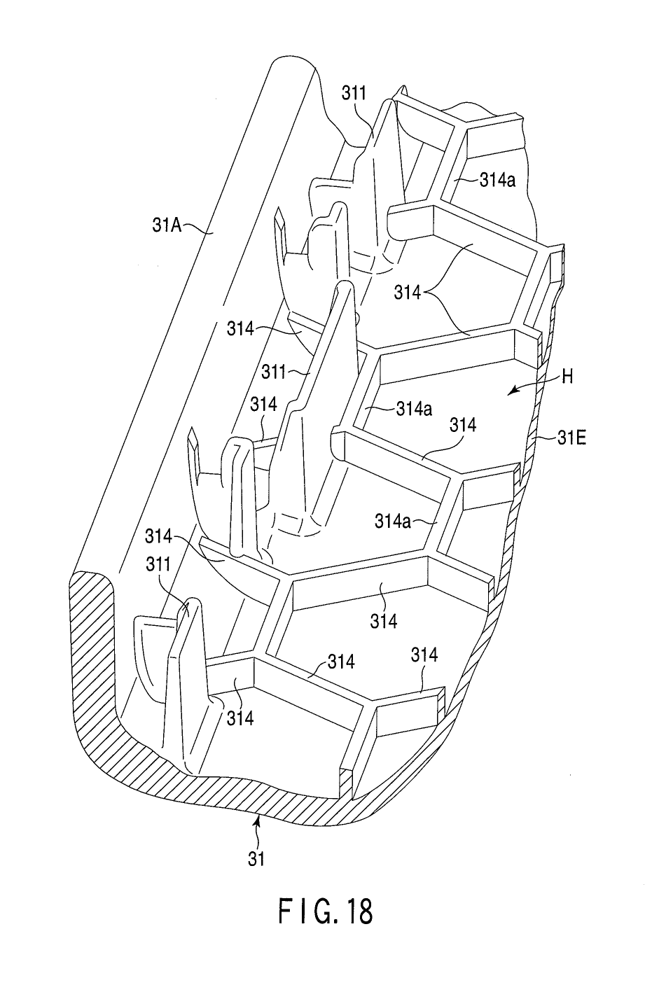

In FIGS. 17 and 18, the ribs 314 arranged to form the honeycomb structure in the vicinity of the sidewall 31A in each of the right area A2 and left area A3 penetrate the supports 311 arranged in front of the sidewall 31A to extend to the sidewall 31A. The ribs 314 are provided by continuing the same pattern of the honeycomb structure to the sidewall 31A beyond the supports 311. Hence, the torsional rigidity of the outer cover 31 is enhanced correspondingly by the inclusion of the effect of the sidewalls 31A and supports 311. As the ribs 314 extend to the sidewalls 31A, it is possible to release the stress toward the sidewalls 31A and supports 311 when torsion is applied to the outer cover. Furthermore, in the ribs 314 provided in the on-diagonal line area A5, and closer to the hinge side corner 31B or rotation end corner 31D, and ribs 314 provided in the lower area A4, and closer to the main body 2, their heights are gradually decreased to the surface of the inner wall 31E, and the ribs 314 are joined to the surface of the inner wall 31E smoothly. Therefore, the stress transmitted to the ribs 314 is not concentrated at the outermost periphery of the honeycomb structure.

It should be noted that in each of the embodiments, although some of the cells H constituted of the ribs 314 provided adjacent to the reinforcement beads 315 and 316 are less than a full regular hexagon, these incomplete cells also constitute part of the honeycomb structure.

It is possible to enhance the rigidity of the enclosure of the display section against a pressing load and torsional stress applied thereto without increasing the number of parts, and weight of the enclosure in the electronic device of embodiments described above.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic device comprising:
an enclosure, a display in the enclosure, the enclosure coupled to a main body by at least one hinge the enclosure comprising an outer cover held at an angle of rotation by the rotation resistance of the at least one hinge and configured to cover the back of a display module in the display;
ribs integral with an inner wall of the outer cover in a honeycomb structure comprising a plurality of cells; and
reinforcement beads integral with the inner wall of the outer cover between the vicinity of the hinge side corners attached to the hinges and the vicinity of the rotation end corners on the outer cover diagonal with respect to the hinge side corners.

2. The electronic device of claim 1, wherein
the height of the ribs is lower than the height of the reinforcement beads.

3. The electronic device of claim 1, wherein
the height the ribs is higher than the height of the reinforcement beads.

4. The electronic device of claim 1, wherein
the outer cover comprises a gradually curved surface comprising a slightly bulging center portion, and
the heights of the ribs and reinforcement beads are in parallel with the display unit.

5. The electronic device of claim 1, wherein
the outer cover comprises a gradually curved surface comprising a slightly bulging center portion, and
the heights of the ribs from the inner wall of the outer cover are identical with each other.

6. The electronic device of claim 1, wherein
each rib in an area substantially close to the main body comprises an end respectively extending at right angles to the main body, and a height of the end of each rib gradually decreases towards the surface of the inner wall of the outer cover.

7. The electronic device of claim 1, wherein
the ribs are in a honeycomb structure comprising longitudinal ribs extending in a direction perpendicular to a rotational axis of the hinges.

8. The electronic device of claim 1, wherein
the outer cover comprises a supporting portion integral with the outer cover and facing the outer periphery of the display module, the supporting portion is along sidewalls extending from the hinge side corners attached to the at least one hinge and at right angles to the rotational axis of the hinges; and
the height of each rib becomes gradually decreases towards the surface of the inner wall of the outer cover in the front of the supporting portion.

9. The electronic device of claim 1, wherein
the outer cover comprises a supporting portion integral with the outer cover and facing the outer periphery of the display module, the supporting portion is along sidewalls extending from the hinge side corners attached to the at least one hinge and at right angles to the rotational axis of the at least one hinge; and
the ribs is extending to the sidewall through the supporting portion.

10. The electronic device of claim 1, wherein
the outer cover comprises a conductive material, and comprises: a portion opened between the rotation end corners to hold an antenna for wireless communication inside the display; and a nonconductive auxiliary cover attached to the portion.

11. The electronic device of claim 1, wherein
at least two of the reinforcement beads are in parallel with each other, and intersect each other at a central area of the outer cover at the same height.

12. The electronic device of claim 11, wherein
the ribs are outside the reinforcement beads in parallel with each other.

13. The electronic device of claim 12, wherein
the ribs are arranged in an area between the reinforcement beads in parallel with each other.

14. The electronic device of claim 12, wherein
the ribs are arranged in an area between the reinforcement beads in parallel with each other, each rib facing the rotation end comprise an end respectively, the height of the end of each rib gradually decreases towards the surface of the inner wall of the outer cover.
